(19) United States
(12) Patent Application Publication
(10) Pub. No.: US 2010/0322272 A1
(43) Pub. Date: Dec. 23, 2010

(54) Minimizing power variations in laser sources

(76) Inventors: Martin Hai Hu, Painted Post, NY (US); David August Sniezek Loeber, Horseheads, NY (US); Dragan Pikula, Horseheads, NY (US); Daniel Ohen Ricketts, Corning, NY (US)

Correspondence Address: CORNING INCORPORATED, SP-TI-3-1, CORNING, NY, 14831, US

(21) Appl. No.: 12/080,852

(22) Filed: Apr. 7, 2008

Related U.S. Application Data
(60) Provisional application No. 61/017,921, filed on Dec. 31, 2007.

(51) Int. Cl. H01S 3/13; H01S 5/12

(52) U.S. Cl. 372/29.021

(57) ABSTRACT

The present invention relates generally to semiconductor lasers and laser projection systems. According to one embodiment of the present invention, a projected laser image is generated utilizing an output beam of the semiconductor laser. A gain current control signal is generated by a gain current feedback loop to control the gain section of the semiconductor laser. Wavelength fluctuations of the semiconductor laser are narrowed by incorporating a wavelength recovery operation in a drive current of the semiconductor laser and by initiating the wavelength recovery operations as a function of the gain current control signal or an optical intensity error signal. Additional embodiments are disclosed and claimed.

### CLAIM OF PRIORITY

This application claims the benefit of U.S. Provisional Patent Application Ser. No. 61/017,921 filed Dec. 31, 2007.

### CROSS REFERENCE TO RELATED APPLICATIONS

The present application is related to copending and commonly assigned U.S. patent application Ser. No. 11/549,856 filed Oct. 16, 2006 (D 20106), but does not claim priority thereto.

### BACKGROUND OF THE INVENTION

The present invention relates generally to semiconductor lasers and, more particularly, to schemes for minimizing laser power variations by utilizing a high speed feedback loop to control the photon density in the laser cavity of the semiconductor laser. The feedback loop is primarily used to control the gain current of the laser and may be combined with other schemes for optimizing the lasing wavelength including, for example, DBR control schemes where the wavelength selective section of a DBR laser is controlled for optimal IR to green conversion in a frequency doubled laser source. The present invention also relates to laser controllers and laser projection systems programmed according to the present invention.

### SUMMARY OF THE INVENTION

The present invention relates generally to semiconductor lasers, which may be configured in a variety of ways. For example and by way of illustration, not limitation, short wavelength sources can be configured for high-speed modulation by combining a single-wavelength semiconductor laser, such as a distributed feedback (DFB) laser, a distributed Bragg reflector (DBR) laser, or a Fabry-Perot laser with a light wavelength conversion device, such as a second harmonic generation (SHG) crystal. The SHG crystal can be configured to generate higher harmonic waves of the fundamental laser signal by tuning, for example, a 1060 nm DBR or DFB laser to the spectral center of a SHG crystal, which converts the wavelength to 530 nm. However, the wavelength conversion efficiency of an SHG crystal, such as MgO-doped periodically poled lithium niobate (PPLN), is strongly dependent on the wavelength matching between the laser diode and the SHG device. As will be appreciated by those familiar with laser design DFB lasers are resonant-cavity lasers using grids or similar structures etched into the semiconductor material as a reflective medium. DBR lasers are lasers in which the etched grating, or other wavelength selective structure, is physically separated from the gain section of the semiconductor laser and may or may not include a phase section used for fine tuning of the lasing wavelength. SHG crystals use second harmonic generation properties of non-linear crystals to frequency-double laser radiation.

A number of factors can affect the wavelength-converted output power of the aforementioned types of laser sources. For example, and not by way of limitation, in the context of a laser source comprising an IR semiconductor laser and a PPLN SHG crystal, temperature and time-dependent variations in IR power over the life of the laser can cause variations in the green output power. Temperature and time-dependent variations in IR beam alignment relative to the SHG waveguide on the input face of the crystal can also lead to variations in the output power of the laser source. Further, over the life of the IR laser and as the operating temperature of the laser varies, the higher order spatial mode content of the IR laser can vary and, since higher order modes typically do not convert to green as efficiently, green output power can also vary.

Mode hopping and uncontrolled large wavelength variations within the laser cavity can also lead to output power variations because the bandwidth of a PPLN SHG device is often very small. For example, a typical PPLN SHG wavelength conversion device, the full width half maximum (FWHM) wavelength conversion bandwidth is only in the 0.16 to 0.2 nm range and mostly depends on the length of the crystal. If the output wavelength of a semiconductor laser moves outside of this allowable bandwidth during operation, the output power of the conversion device at the target wavelength can drop drastically. In laser projection systems, in particular, mode hops are particularly problematic because they can generate instantaneous changes in power that will be readily visible as defects in specific locations in the image.

In typical RGB projection systems that utilize wavelength conversion devices, variations in IR power from any of the aforementioned sources can cause green power to change and create errors in the color balance of the projected image. The present inventors have recognized potentially beneficial schemes for stabilizing output power by controlling photon density in the laser cavity as a function of gain current or a wavelength-converted output intensity error signal.

For example, according to one embodiment of the present invention, a method of minimizing laser wavelength variations in a semiconductor laser is provided. According to the method, a projected laser image is generated utilizing an output beam of the semiconductor laser. A gain current control signal is generated by a gain current feedback loop to control the gain section of the semiconductor laser. Wavelength fluctuations of the semiconductor laser are narrowed by incorporating a wavelength recovery operation in a drive current of the semiconductor laser and by initiating the wavelength recovery operations as a function of the gain current control signal or a wavelength-converted output intensity error signal.

According to another embodiment of the present invention, a system for generating a projected laser image is provided. The system comprises at least one semiconductor laser, projection optics, an optical intensity monitor, and a controller, and the controller is programmed to initiate the wavelength recovery.

The present inventors have recognized that although the concepts of the present invention are described primarily in the context of DBR lasers, it is contemplated that the control schemes discussed herein will also have utility in a variety of types of semiconductor lasers, including but not limited to DFB lasers, Fabry-Perot lasers, and many types of external cavity lasers.

### BRIEF DESCRIPTION OF THE DRAWINGS

The following detailed description of specific embodiments of the present invention can be best understood when read in conjunction with the following drawings, where like structure is indicated with like reference numerals and in which:

FIG. 1A is a schematic illustration of a laser projection system suitable for executing various laser control schemes according to particular embodiments of the present invention;

FIG. 1B is a schematic illustration of a feedback loop suitable for executing various laser control schemes according to particular embodiments of the present invention;

FIG. 2 illustrates the evolution of wavelength, gain current and frequency-converted output power over time;

FIGS. 3 and 4 illustrate the evolution of emission wavelength as a function of gain current in a DBR laser;

FIG. 5 illustrates a scheme for controlling laser wavelength according to one embodiment of the present invention;

FIG. 6 is a further illustration of the control scheme illustrated in FIG. 5;

FIG. 7 illustrates a scheme for controlling laser wavelength according to another embodiment of the present invention; and

FIG. 8 is a further illustration of the control scheme of FIG. 7.

### DETAILED DESCRIPTION

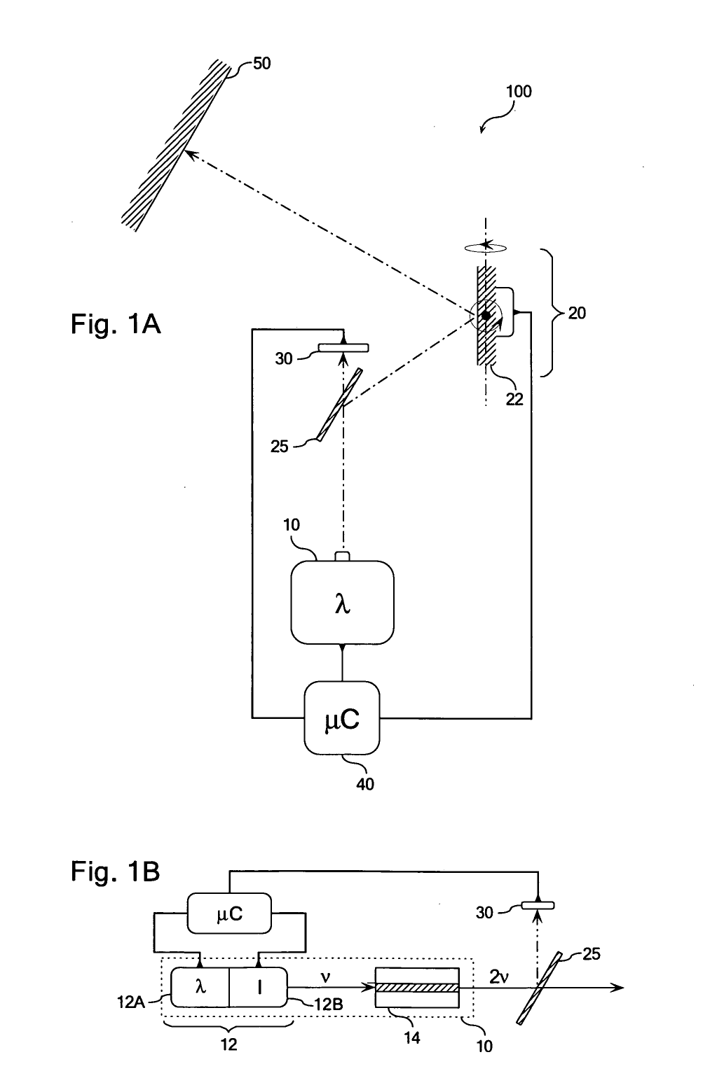

Referring to FIGS. 1A and 1B, the concepts of the present invention may be conveniently illustrated with general reference to a laser source 10 comprising a two-section DBR-type semiconductor laser 12, although the concepts of the present invention can be executed in the context of various types of semiconductor lasers, the design and operation of which is described generally above and is taught in readily available technical literature relating to the design and fabrication of semiconductor lasers. In the context of a frequency-doubled light source of the type illustrated in FIG. 1B, the DBR laser 12 is optically coupled to a light wavelength conversion device 14. The light beam emitted by the semiconductor laser 12 can be either directly coupled into the waveguide of the wavelength conversion device 14 or can be coupled through collimating and focusing optics or some other type of suitable optical element or optical system. The wavelength conversion device 14 converts the incident light v into higher harmonic waves 2v and outputs the converted signal.

This type of configuration is particularly useful in generating shorter wavelength laser beams from longer wavelength semiconductor lasers and can be used, for example, as a visible laser source 10 for a single-color laser projection system 100 or a multi-color RGB laser projection system comprising, for example, the laser source 10, laser projection optics 20, a partially reflective beam splitter 25, an optical intensity monitor 30, and a controller 40, which may be stand-alone laser controller or a programmable projection controller incorporating a laser controller. The laser projection optics 20 may comprise a variety of optical elements including, but not limited to, a two-axis, gimbal mounted, MEMS scanning mirror 22. These optical elements cooperate to generate a two-dimensional scanned laser image on a projection screen or image field 50.

The partially reflective beam splitter 25 directs a portion of the light generated by the laser source 10 to the optical intensity monitor 30. The optical intensity monitor 30 is configured to generate an electrical or optical signal representing variations in the intensity of the light generated by the laser source. The controller 40, which is in communication with the optical intensity monitor 30, receives or samples the signal from the optical intensity monitor 30 and can be programmed to control the laser source as a function of the sampled intensity, as is explained in further detail below. It is contemplated that a variety of alternative configurations may be utilized to monitor the intensity of the output beam without departing from the scope of the present invention. It is noted that the beam splitter 25, the laser source 10, the optical intensity monitor 30, and the controller 40 are merely illustrated schematically in FIGS. 1A and 1B, and that their respective positions and orientations relative to each other and any system housing may vary widely according to the specific needs of the particular field in which the system is utilized. For example, and not by way of limitation, it is noted that the beam splitter 25 and optical intensity monitor 30 may be positioned within, or external to, a housing for the laser source.

The DBR laser 12 illustrated schematically in FIG. 1B comprises a wavelength selective section 12A and a gain section 12B. The wavelength selective section 12A, which can also be referred to as the DBR section of the laser 12, typically comprises a first order or second order Bragg grating positioned outside the active region of the laser cavity. This section provides wavelength selection, as the grating acts as a mirror whose reflection coefficient depends on the wavelength. The gain section 12B of the DBR laser 12 provides the major optical gain of the laser. A phase matching section may also be employed to create an adjustable phase shift between the gain material of the gain section 12B and the reflective material of the wavelength selective section 12A. The wavelength selective section 12A may be provided in a number of suitable alternative configurations that may or may not employ a Bragg grating.

The wavelength conversion efficiency of the wavelength conversion device 14 illustrated in FIG. 1B is dependent on the wavelength matching between the DBR laser 12 and the wavelength conversion device 14. The output power of the higher harmonic light wave generated in the wavelength conversion device 14 drops drastically when the output wavelength of the DBR laser 12 deviates from the wavelength conversion bandwidth of the wavelength conversion device 14. For example, when a semiconductor laser is modulated to produce data, the thermal load varies constantly. The resulting change in laser temperature and lasing wavelength generates a variation of the efficiency of the associated SHG crystal. In the case of a wavelength conversion device 14 in the form of a 12 mm-long PPLN SHG device, a temperature change in the DBR laser 12 of about 2° C. will typically be enough to take the output wavelength of the laser 12 outside of the 0.16 nm full width half maximum (FWHM) wavelength conversion bandwidth of the wavelength conversion device 14. The present invention addresses this problem by limiting laser wavelength variations to acceptable levels.

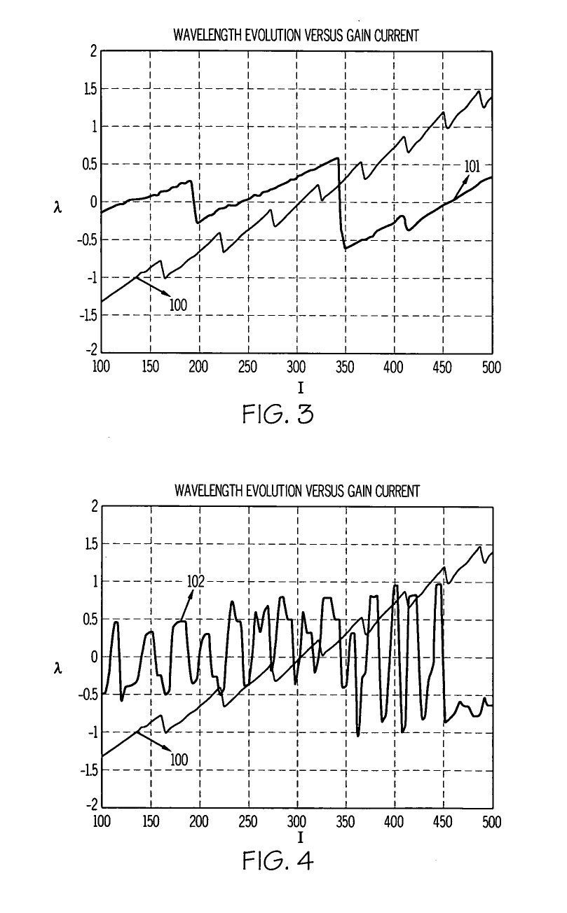

As is noted above, a number of factors can affect the wavelength-converted output power of the aforementioned types of laser sources, one example of which is mode hopping and uncontrolled large wavelength variations within the laser cavity. FIG. 3 illustrates the evolution of emission wavelength λ, illustrated in arbitrary units, as a function of gain current I, also illustrated in arbitrary units, in a DBR laser. When the gain current increases, the temperature of the gain section also increases. As a consequence, the cavity modes move towards higher wavelengths. Because the wavelength of the cavity modes move faster than the nominal wavelength selected by the DBR section, the laser reaches a point where a cavity mode of lower wavelength is closer to the maximum of the DBR reflectivity curve. At that point, the mode of lower wavelength has lower loss than the mode that is established and the laser then automatically jumps to the mode that has lower loss. This behavior is illustrated on the curve 100 of FIG. 3. As is illustrated in FIG. 3, the wavelength slowly increases and includes sudden mode hops whose amplitude is equal to one free spectral range of the laser cavity. These single mode hops are not necessarily a serious problem. Indeed, in the case of frequency doubling PPLN applications, for instance, the amplitude of those mode hops are smaller than the spectral bandwidth of the PPLN. So, the image noise associated with those small mode hops remains within acceptable amplitudes.

Referring further to FIG. 3, curve 101 illustrates significantly different emission behavior in a DBR laser. Specifically, a laser having the same general manufacturing parameters as the laser illustrated with reference to curve 100, may exhibit significantly different behavior in the sense that, instead of having mode hops with an amplitude of one laser free spectral range, the laser will exhibit mode hops having up to 6 or more free spectral range amplitudes. For many applications, this large sudden wavelength variation would not be acceptable. For example, in the case of a laser projection system, these large hops would cause sudden intensity jumps in the image from a nominal grey-scale value to a value close to zero. The present inventors have investigated this phenomena, as well as wavelength instability and hysteresis in lasers, and note that these laser emission defects can be attributed to one or more of a variety of factors, including spatial hole burning, spectral hole burning, gain profile broadening, and self induced Bragg gratings. It is contemplated that these factors may lock lasing on the particular cavity mode that has been established in the laser cavity or encourage larger mode hops. Indeed, it appears that once a mode is established, the photons that are inside the cavity at a specific wavelength disturb the laser itself by depleting the carrier density at a specific energy level or by creating a self induced Bragg grating in the cavity. It is also noted that the interaction of these phenomena does not lend itself to a simple or closed form, predictive or model-based solution.

The curve 102 of FIG. 4 illustrates another case of special mode hopping behavior. In the illustrated case, the emission wavelength λ, illustrated in arbitrary units, is unstable because it includes back reflections attributable to a component located outside the laser, a phenomena referred to as the external cavity effect. With the external cavity effect, an external reflection creates a parasitic Fabry-Perot cavity that disturbs the laser cavity and is capable of generating mode hops of very large amplitude. Regardless of the source of unacceptable wavelength drift in a semiconductor laser, the present invention is directed at minimizing wavelength fluctuations and narrowing the time-average laser oscillation optical bandwidth of the laser.

The present inventors have recognized that the large wavelength fluctuations and associated mode-hopping effect illustrated in FIGS. 3 and 4 is at least partially dependent upon photon density in the laser cavity and can be amplified when having significant external cavity effects. The present inventors have also recognized that the lasing wavelength may jump more than one mode and that this multi-mode jump may be attributable, in whole or in part, to spectral and spatial hole burning and additional lasing phenomena such as external cavity effects.

Regardless of the cause of multi-mode drift in semiconductor lasers, when this phenomenon occurs, the lasing wavelength usually shows abnormal wavelength jumps which are equal to a multiple of the cavity mode spacing. Before a large mode hop occurs, the laser usually shows large continuous wavelength shift. The larger wavelength drift and the abnormal wavelength jump can cause unacceptable noise in a laser signal. For example, if this phenomenon happens systematically in a laser projection system the noise in the projected image will be readily visible to the human eye.

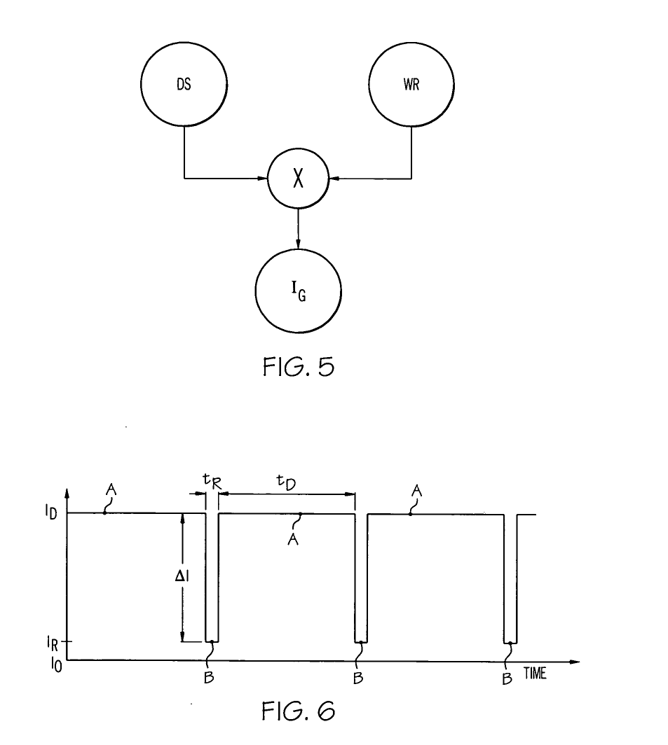

As is noted above, the present invention generally relates to control schemes where a semiconductor laser drive current comprises a drive portion and a suitably timed wavelength recovery portion. FIGS. 5 and 6 illustrate a scheme for controlling wavelength in a single mode laser signal where the drive portion comprises a data portion that is injected as electrical current into the gain section of the semiconductor laser. Accordingly, in the illustrated embodiment, the drive current comprises a data portion and a wavelength recovery portion. Referring specifically to FIG. 5, these portions of the drive current or gain injection current (I_{G}) can be introduced by taking the product of a laser data signal (DS) and a suitably configured wavelength recovery signal (WR). For example, and not by way of limitation, the laser data signal may carry image data for projection in a laser projection system. As is illustrated in FIG. 6, the wavelength recovery signal is configured such that the data portion of the gain section drive current, i.e., the gain injection current, comprises a relatively high drive amplitude I_{D} of relatively long drive duration t_{D}, while the wavelength recovery portion of the drive current comprises a relatively low recovery amplitude I_{R} of relatively short recovery duration t_{R}. The relatively high drive amplitude I_{D} of the data portion is sufficient for lasing within the laser cavity at a lasing mode λ₀. The relatively low recovery amplitude I_{R} of the wavelength recovery portion of the drive current is distinct from the drive amplitude I_{D} and is illustrated in FIG. 6 as being ΔI lower than the drive amplitude I_{D}.

The drive amplitude I_{D} and duration t_{D} of the data portion of the gain section drive current I_{G} act to produce the optical signal with appropriate power and wavelength, depending of course on the specific application in which it is to be used. Although the drive amplitude I_{D} is illustrated in FIG. 6 in relatively simple form, the gain section drive current I_{G} may also comprise a correction component I_{ADJ} that is used to compensate for relatively low level wavelength drift in the semiconductor laser. For example, as conversion efficiency drops, the correction component I_{ADJ} can be used to increase the gain current I_{G} to maintain constant output power. The correction component I_{ADJ} can also be used to decrease the gain current I_{G} when needed. However, when the wavelength drift increases to relatively high levels, the gain section drive current I_{G} will exceed an acceptable value and the aforementioned wavelength recovery operation will be executed. Typically, the wavelength recovery operation is not executed on a periodic basis because the behavior of the gain current I_{G} is aperiodic.

The recovery amplitude I_{R} and the recovery duration t_{R} are sufficient to decrease photon density within at least a portion of the laser cavity. By decreasing the photon density to a lower value, in many cases close to zero, the various phenomena that cause large wavelength drift, such as spectral hole burning, spatial hole burning, gain profile broadening, or self induced Bragg gratings, disappear. As a consequence, when significant current is re-injected into the gain section at the end of the recovery period, the laser automatically selects the modes that are among the closest to the maximum of the DBR reflectivity curve. Therefore, the wavelength fluctuations can be limited to one laser free spectral range and the multi-cavity mode hops are eliminated, or at least significantly reduced. The resulting gain section drive current, which comprises the data portion and the wavelength recovery portion can be used to minimize wavelength drift and narrow the time-average laser oscillation optical bandwidth of the laser.

Stated differently, the drive amplitude I_{D} and duration t_{D} of the data portion of the gain section drive current increase the probability that the lasing wavelength will undergo an unacceptable drift. For example, and not by way of limitation, it is contemplated that a change in wavelength that exceeds 0.05 nm would constitute an unacceptable wavelength drift. The relatively low recovery amplitude I_{R} of the density recovery portion of the gain section drive current follows the data portion of the drive current and decreases the probability of an unacceptable wavelength drift.

It is noted that the wavelength recovery signal does not need to be implemented on a regular, periodic basis. Rather, the recovery signal can be applied as-needed to shut off a lasing cavity mode before it has accumulated large wavelength drift. Periodic wavelength recovery effectively causes the laser to choose a wavelength according to a probability distribution function, which would limit the probability of a wavelength match. In contrast, by executing the wavelength recovery operation on an as needed basis, after few shutdowns, the probability of a wavelength match would increase exponentially.

In terms of frequency of the recovery period, it generally needs to be frequent enough to limit the wavelength variation between two recovery periods to an acceptable amplitude. In the embodiment of the present invention illustrated in FIGS. 1A and 1B, the optical intensity monitor 30, the controller 40, and the laser source 10, form a gain current feedback loop in which the controller 40 receives or samples the signal from the optical intensity monitor 30 and is programmed to control the gain section 12B of the DBR laser 12 as a function of the sampled intensity.

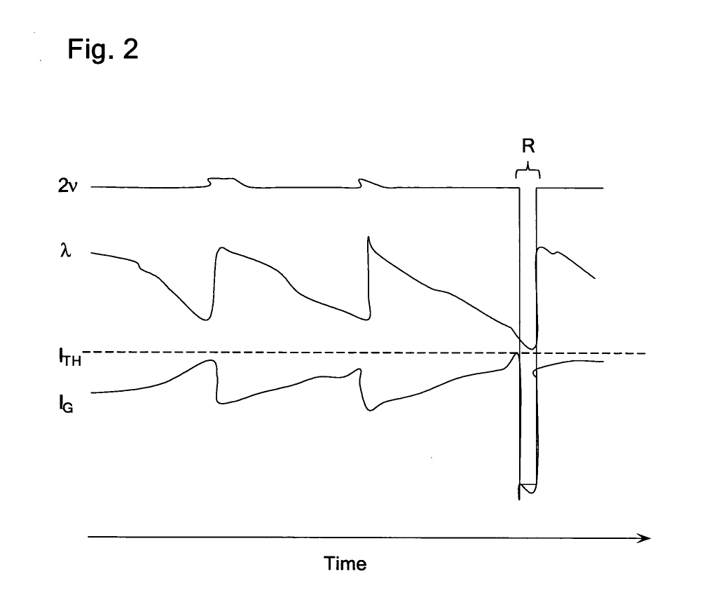

More specifically, referring to FIG. 1B, if the signal from the optical intensity monitor 30 indicates an unacceptably low or high output intensity in the frequency-doubled signal from the wavelength conversion device 14, the gain current control signal can be used to control the gain section of the DBR laser 12 to increase or decrease gain in the DBR laser 12. In addition, the aforementioned wavelength recovery operation can be initiated as a function of the gain current control signal. For example, referring to FIG. 2, the wavelength recovery operation can be initiated when the gain current control signal I_{G} gets too high, i.e., when it exceeds a particular recovery threshold value I_{TH}. The resulting recovery event R is illustrated clearly in FIG. 2 as a temporary drop in the gain current control signal I_{G} and a corresponding drop in frequency-converted output power 2v. The recovery event R is not necessarily periodic. Typical wavelength behavior λ over time is also illustrated in FIG. 2.

Alternatively, the wavelength recovery operation can be initiated when the gain current control signal exceeds a recovery threshold value for a given duration, when an integral of the gain current control signal exceeds the recovery threshold, or at any other time when the history or current state of the gain current control signal indicates an operating condition where execution of the wavelength recovery operation would be advantageous, i.e., where the targeted emission wavelength has drifted an unaccepted amount. The wavelength recovery operation can also be initiated as a function of an optical intensity error signal, which could merely be generated from a comparison of a reference intensity and an optical intensity signal generated by the optical intensity monitor 30. The evolution of the optical intensity error signal and the wavelength recovery operation over time would be analogous to that illustrated in FIG. 2, with the exception that the optical intensity error signal would trigger the recovery operation, as opposed to the gain current control signal I_{G}.

As is illustrated in FIG. 1B, in particular embodiments of the present invention, the DBR laser 12 can include a wavelength selective section 12A in addition to the gain section 12B. In addition, the DBR laser 12, the optical intensity monitor 30, and the controller 40 can be configured to form a DBR feedback loop that can be used to control the wavelength selective section 12A of the laser 12 to minimize the gain current control signal. More specifically, because the gain current is adjusted to deliver target green power, the DBR control loop can be configured to look at the gain current control signal or the intensity signal generated by the optical intensity monitor 30 and control the wavelength selective section 12A to adjust the DBR wavelength to minimize the gain required in the gain section 12B. It is contemplated that the DBR feedback loop is illustrated schematically in FIG. 1B and may take a variety of forms.

In the context of a laser projection system including, for example, a frequency doubled PPLN green laser, without wavelength control according to the present invention, the green power emitted by the laser over a single line of the image display will exhibit sudden variations in power due to multiple cavity mode hops. As a result, projected images will have abrupt drops in power with amplitude on the order of 50% and more. However, employing wavelength control schemes according to the present invention where the drive signal is altered at suitable intervals, it is contemplated that the undesired decrease in laser power will be highly mitigated and the projected image will exhibit defects with relatively high spatial frequency, which are typically not readily apparent to the naked eye.

Although the recovery amplitude I_{R} may be zero, it can be any value that is sufficient to eliminate the source of multiple cavity mode hops or otherwise improve the wavelength behavior of the laser. The recovery amplitude I_{R} of the gain section drive current will be lower than the drive amplitude I_{D} and can be substantially above zero. The relatively high drive amplitude I_{D} may be substantially continuous but will often vary in intensity, particularly where the semiconductor laser is incorporated in an image projection system, as is illustrated in FIG. 1A.

Where the laser is configured for optical emission of encoded data, a data signal representing the encoded data is applied to the laser. For example, and not by way of limitation, the data signal may be incorporated as an intensity or pulse-width modulated data portion of a drive signal injected into the gain section of the laser. The wavelength recovery operation of the present invention can be executed to be at least partially independent of the data encoded in the data signal. For example, where the drive current is injected into the gain section of the laser, its drive portion may be intensity modulated to encode data. The wavelength recovery portion of the drive current is superimposed on the drive current, independent of the encoded data. Similarly, where the drive portion is pulse-width modulated to encode data, the wavelength recovery portion of the drive current will also be superimposed on the drive current.

The aforementioned superposition may be completely independent of the encoded data or may be applied only where the intensity of the drive current or the duration of the pulse width representing the encoded data reaches a threshold value, in which case it would be partially dependent on the encoded data. Once superimposed, however, the extent of independence of the wavelength recovery portion would need to be sufficient to ensure that sufficient wavelength recovery would be obtained. Stated differently, the wavelength recovery portion of the drive current should dominate the drive current under conditions where the data signal would otherwise prevent wavelength recovery. For example, in the context of a pulse-width modulated data signal, it is contemplated that wavelength recovery may not be needed for relatively short, high amplitude pulse-widths. However, where the encoded data includes relatively long, high amplitude pulse widths, the duty cycle defined by the drive operation and wavelength recovery operation should be sufficient to limit the maximum duration of the high amplitude pulse width to ensure that wavelength recovery can be achieved before unacceptable wavelength drift is observed. For example, it may be preferable to ensure that the maximum duration of the pulse width cannot exceed about 90% of the duration of the duty cycle defined by the drive operation and wavelength recovery operation. In addition, in the context of pulse-width modulated data, care should also be taken to ensure that the recovery amplitude I_{R} of the wavelength recovery portion is below the threshold lasing current of the semiconductor laser or sufficiently low to recover the wavelength.

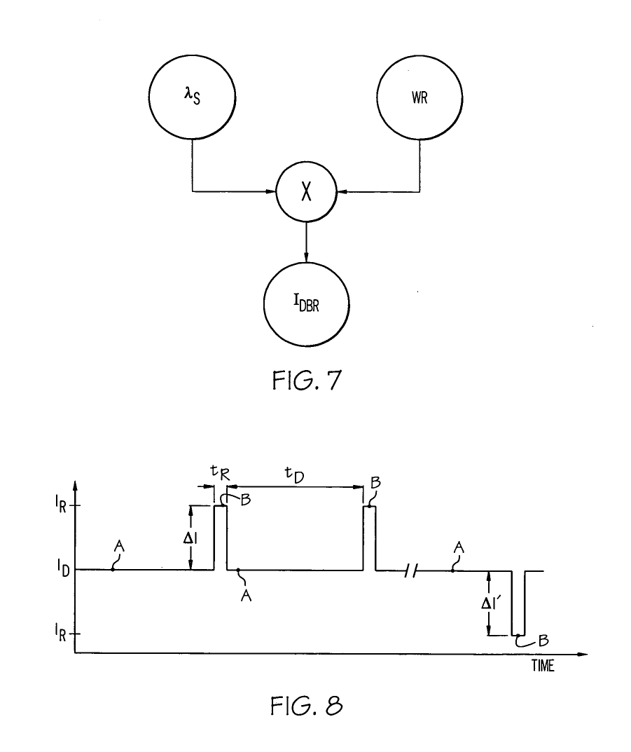

FIGS. 7 and 8 illustrate a scheme for controlling wavelength in a single mode laser signal where the aforementioned drive portion of the semiconductor laser drive current comprises a wavelength control signal (λ_{S}) injected into the wavelength selective section of the semiconductor laser. Accordingly, the drive current injected into the wavelength selective section of the semiconductor laser comprises the wavelength control portion and a wavelength recovery portion. As is noted above, this drive current is also referred to herein as the DBR injection current (I_{DBR}) because the wavelength selective section of a DBR laser is commonly referred to as the DBR section of the laser.

Referring specifically to FIG. 7, the wavelength control portion and the wavelength recovery portion of the DBR injection current can be introduced by taking the product of a standard DBR wavelength control signal (λ_{S}) and a suitably configured wavelength recovery signal (WR) according to the present invention. As is illustrated in FIG. 8, the wavelength recovery signal is configured such that the wavelength control portion of the DBR injection current comprises a drive amplitude I_{D} of relatively long drive duration t_{D}, while the wavelength recovery portion of the drive current comprises a recovery amplitude I_{R} of relatively short recovery duration t_{R}. The recovery amplitude I_{R} of the wavelength recovery portion of the DBR injection current is distinct from the drive amplitude I_{D}, may be lower or higher than the drive amplitude I_{D}, and is illustrated in FIG. 8 as differing from drive amplitude I_{D} by ΔI or ΔI′.

The amplitude I_{D} of the wavelength control portion is sufficient to keep the DBR wavelength tuned to the adequate wavelength which, in the case of a frequency doubled PPLN laser is fixed by the wavelength of the doubling crystal. When the DBR current is changed to the recovery amplitude I_{R}, which is sufficiently different from the drive amplitude I_{D}, the Bragg wavelength is shifted to a different wavelength and a new cavity mode begins to lase. The original lasing cavity mode is turned off. If the new cavity mode is sufficiently displaced from the original lasing cavity mode, the phenomena that are responsible for multiple cavity mode hops will disappear, or substantially dissipate, at the laser nominal targeted wavelength. At the end of the DBR recovery pulse, the DBR current is returned to its original level, shifting the Bragg wavelength back to its original position. At this time, the new cavity mode is turned off and lasing resumes at a recovered mode at or near the original Bragg wavelength, under the recovered optical gain spectrum. It is contemplated that the resulting image will have attributes similar to those discussed above with respect to the control scheme of FIGS. 5 and 6

Although the present invention is described in the context of controlling the gain or DBR sections of a DBR laser via current injection, it is contemplated that either or both of these portions of the laser source 10 could be controlled via microheaters thermally coupled to the respective portions of the laser. Given the fact that microheater control typically represents a response mechanism that is slower than that represented by laser control via current injection, it may be preferable to ensure that control of the wavelength recovery operation be executed using current injection, as opposed to microheaters. Accordingly, hybrid configurations are contemplated where the standard control handle for the laser would be facilitated through microheater technology, while current injection mechanisms would be provided for wavelength recovery.

One contemplated explanation of the theoretical basis for the embodiment of the present invention illustrated in FIGS. 7 and 8 is that the scheme essentially changes the photon standing wave at the gain-compressed wavelength to another wavelength outside the spectral hole burning region. The duration of the change in the standing wave is relatively brief, typically only long enough to remove the spectral hole burning and recover the original gain spectrum. It is contemplated that the wavelength shift induced under the recovery amplitude I_{R} may vary in magnitude but will often preferably be equivalent to a wavelength shift of at least about two lasing modes. Indeed, it is contemplated that the wavelength shift may be so large as to disable lasing with the laser cavity. It is also contemplated that the control scheme of FIGS. 7 and 8 can be applied to external cavity semiconductor lasers by changing the external feedback to temporarily move the lasing wavelength out of the original position in order for the carriers to fill the spectral hole.

Referring to the laser projection system illustrated schematically in FIG. 1A, it is noted that the drive current control schemes according to the present invention may be executed in a variety of forms within the system. For example, and not by way of limitation, the wavelength recovery portion of the drive current may be executed by integrating the recovery portion into the video signal during rendering by the projection software and electronics. Alternatively, the wavelength recovery portion of the drive signal may be integrated into the laser driver electronics. In this approach, the drive signal, which is derived from the image stream, would be periodically overridden by the wavelength recovery signal prior to current scaling. As a further alternative, the drive current to the laser could be periodically shunted, or otherwise reduced, to reduce or modify the drive current independent of the desired intensity level.

It is contemplated that FIGS. 5-8 illustrate laser operation schemes that may be used alternatively or together to reduce noise in a single mode laser signal. Further, the schemes of FIGS. 5-8 may be used in systems incorporating one or more single mode lasers. For example, as is described in further detail below, it is contemplated that the schemes of FIGS. 5-8 may be used alternatively or together in laser image projection systems incorporating one or more single mode lasers. It is also noted that reference herein to single mode lasers or lasers configured for single mode optical emission should not be taken to restrict the scope of the present invention to lasers that operate in a single mode exclusively. Rather, the references herein to single mode lasers or lasers configured for single mode optical emission should merely be taken to imply that lasers contemplated according to the present invention will be characterized by an output spectrum where a single mode of broad or narrow bandwidth is discernable therein or by an output spectrum that is amenable to discrimination of a single mode therefrom through suitable filtering or other means.

Additional considerations need to be accounted for when establishing the respective values of the drive duration t_{D} the recovery duration t_{R} in the context of laser projection systems. For example, and not by way of limitation, in the context of a scanning laser projection system illustrated similar to that illustrated in FIG. 1A, the scanned image is composed of a series of image frames comprising a series of image lines form by a succession of image pixels. The active pixel duration of a pixel in the image may be 40 nsec or less. Generally, the recovery duration t_{R} will be less than the pixel duration t_{P}. Preferably, the recovery duration t_{R} is at least 50% less than the pixel duration t_{P}. In contrast, the drive duration t_{D} may be greater than, less than, or equal to the pixel duration t_{P}, depending upon the preferences of the system designer.

Those skilled in the art will recognize that the active pixel duration t_{P} may vary modestly and periodically across the image as a result of scanning speed variations. Accordingly, reference to a projecting system that is “characterized by an active pixel duration” should not be taken to denote that each pixel in an image has the same pixel duration. Rather, it is contemplated that individual pixels within the display may have different pixel durations that each fall under the general concept of a display characterized by an active pixel duration t_{P}.

A multi-tone image can be generated by the image projection system by configuring the image projection electronics and the corresponding laser drive currents to establish a pixel intensity that varies across the array of image pixels. In this case, the wavelength recovery portion of the drive current is superimposed upon the signal that encodes the varying pixel intensity. Further detail concerning the configuration of scanning laser image projection systems and the manner in which varying pixel intensities are generated across an image is beyond the scope of the present invention and may be gleaned from a variety of readily available teachings on the subject.

It is contemplated that other types of laser projection systems, such as spatial light modulator based systems (including digital light processing (DLP), transmissive LCD, and liquid crystal on silicon (LCOS)), incorporating laser-based light sources may benefit from the wavelength stabilization techniques described herein. In these other systems the relevant period exogenous to the laser is not the pixel period but the inverse of the screen refresh rate, or a fraction thereof. In these cases the input signal to the laser will be characterized by an encoded data period t_{P} and the drive current will be configured such that the recovery duration t_{R} of the wavelength recovery portion is less than the encoded data period t_{P}.

Reference is made throughout the present application to various types of currents. For the purposes of describing and defining the present invention, it is noted that such currents refer to electrical currents. Further, for the purposes of defining and describing the present invention, it is noted that reference herein to “control” of an electrical current does not necessarily imply that the current is actively controlled or controlled as a function of any reference value. Rather, it is contemplated that an electrical current could be controlled by merely establishing the magnitude of the current.

It is to be understood that the preceding detailed description of the invention is intended to provide an overview or framework for understanding the nature and character of the invention as it is claimed. It will be apparent to those skilled in the art that various modifications and variations can be made to the present invention without departing from the spirit and scope of the invention. Thus, it is intended that the present invention cover the modifications and variations of this invention provided they come within the scope of the appended claims and their equivalents.

For example, although the control schemes described herein relate to the incorporation of a wavelength recovery portion in a drive current applied to a gain section or wavelength selective DBR section of a semiconductor laser, it is contemplated that methods of incorporating the wavelength recovery operation of the present invention in a laser operating scheme are not limited to drive currents applied to only these portions of a laser. For example, and not by way of limitation, the laser may include a recovery portion that is configured to absorb photons when a recovery signal is applied thereto. In which case, the recovery portion can be used to decrease photon density as needed, in a manner similar that which is employed for the gain and DBR sections described herein.

It should be further understood that references herein to particular steps or operations that are described or claimed herein as being performed “as a function” of a particular state, condition, value, or other type of variable or parameter should not be read to limit execution of the step or operation solely as a function of the named variable or parameter. Rather, it should be understood that additional factors may play a role in the performance of the step or operation. For example, particular embodiments of the present invention recite initiation of a wavelength recovery operation as a function of a gain current control signal but this recitation should not be read to limit execution of the operation solely as a function of the gain current control signal.

It is noted that terms like “preferably,” “commonly,” and “typically,” when utilized herein, are not intended to limit the scope of the claimed invention or to imply that certain features are critical, essential, or even important to the structure or function of the claimed invention. Rather, these terms are merely intended to highlight alternative or additional features that may or may not be utilized in a particular embodiment of the present invention. Further, it is noted that reference to a value, parameter, or variable being a “function of” another value, parameter, or variable should not be taken to mean that the value, parameter, or variable is a function of one and only one value, parameter, or variable.

For the purposes of describing and defining the present invention it is noted that the term “substantially” is utilized herein to represent the inherent degree of uncertainty that may be attributed to any quantitative comparison, value, measurement, or other representation. The term “substantially” is also utilized herein to represent the degree by which a quantitative representation. e.g., “substantially above zero,” varies from a stated reference, e.g., “zero,” and should be interpreted to require that the quantitative representation varies from the stated reference by a readily discernable amount.

It is also noted that recitations herein of a component of the present invention being “configured” or “programmed” in a particular way, to embody a particular property, or function in a particular manner, are structural recitations as opposed to recitations of intended use. More specifically, the references herein to the manner in which a component is “configured” or “programmed” denote an existing physical condition of the component and, as such, are to be taken as a definite recitation of the structural characteristics of the component.

What is claimed:

1. A method of operating a system for generating a projected laser image, the system comprising at least one laser source, an optical intensity monitor, and a controller, wherein the laser source comprises a semiconductor laser optically coupled to a wavelength conversion device, the optical intensity monitor and the controller form at least a portion of a gain current feedback loop configured to control a gain section of the semiconductor laser as a function of optical intensity and the method comprises:
generating a projected laser image utilizing an output beam of the semiconductor laser;
utilizing a gain current control signal generated by the gain current feedback loop to control the gain section of the semiconductor laser; and
narrowing wavelength fluctuations of the semiconductor laser by incorporating a wavelength recovery operation in a drive current of the semiconductor laser, wherein the wavelength recovery operation is sufficient to deplete photon density at a targeted wavelength of the semiconductor laser and is initiated as a function of the gain current control signal.

2. A method as claimed in claim 1 wherein the wavelength recovery operation is further initiated as a function of an optical intensity error signal.

3. A method as claimed in claim 2 wherein the optical intensity error signal is generated from a comparison of a reference intensity and an optical intensity signal generated by the optical intensity monitor.

4. A method as claimed in claim 1 wherein the wavelength recovery operation is initiated when the gain current control signal exceeds a recovery threshold.

5. A method as claimed in claim 1 wherein the wavelength recovery operation is initiated when an integral of the gain current control signal exceeds a recovery threshold.

6. A method as claimed in claim 1 wherein the wavelength recovery operation is initiated when the gain current control signal exceeds a recovery threshold value for a given duration.

7. A method as claimed in claim 1 wherein the wavelength recovery operation is initiated when the state or history of the gain current control signal indicates unacceptable wavelength drift in the targeted wavelength of the semiconductor laser.

8. A method as claimed in claim 1 wherein:
the projected laser image comprises an array of image pixels, each of the image pixels being characterized by an active pixel duration t_{P}; and
a duration of the wavelength recovery operation is less than the active pixel duration t_{P}.

9. A method as claimed in claim 1 wherein the drive current comprises a data portion representing the projected laser image and a wavelength recovery portion representing the wavelength recovery operation.

10. A method as claimed in claim 1 wherein:
the semiconductor laser further comprises a wavelength selective section; and
the semiconductor laser, the optical intensity monitor and the controller form at least a portion of a DBR feedback loop configured to control the wavelength selective section of the semiconductor laser.

11. A method as claimed in claim 10 wherein the DBR feedback loop is configured to minimize the gain current control signal.

12. A method as claimed in claim 10 wherein the DBR feedback loop is configured to control the wavelength selective section of the semiconductor laser as a function of the gain current control signal generated by the gain current feedback loop.

13. A method as claimed in claim 10 wherein the DBR feedback loop is configured to control the wavelength selective section of the semiconductor laser as a function of optical intensity, as monitored by the optical intensity monitor.

14. A method as claimed in claim 1 wherein:
the semiconductor laser is comprised within a laser projection system;
the laser projection system comprises at least one additional semiconductor laser configured for lasing at respective lasing wavelengths distinct from the target emission wavelength of the semiconductor laser;
the laser projection system further comprises image projection electronics and laser projection optics operative to generate a projected image comprising an array of image pixels; and
the method further comprises operating the semiconductor laser and the additional lasers such that at least one of the image pixels is illuminated thereby.

15. A system for generating a projected laser image, the system comprising at least one laser, projection optics, an optical intensity monitor, and a controller, wherein:
the laser source comprises a semiconductor laser optically coupled to a wavelength conversion device;
the semiconductor laser, the optical intensity monitor and the controller form at least a portion of a gain current feedback loop configured to control a gain section of the semiconductor laser as a function of optical intensity;
the controller, the semiconductor laser, and the projection optics are configured to generate a projected laser image utilizing an output beam of the semiconductor laser;
the controller is programmed to utilize a gain current control signal generated by the gain current feedback loop to control the gain section of the semiconductor laser and narrow wavelength fluctuations of the semiconductor laser by incorporating a wavelength recovery operation in a drive current of the semiconductor laser; and
the wavelength recovery operation is initiated as a function of the gain current control signal and is sufficient to deplete photon density at a targeted wavelength of the semiconductor laser.

16. A method of operating a system for generating a projected laser image, the system comprising at least one laser source, an optical intensity monitor, and a controller, wherein the laser source comprises a semiconductor laser optically coupled to a wavelength conversion device, the optical intensity monitor and the controller form at least a portion of a gain current feedback loop configured to control a gain section of the semiconductor laser as a function of optical intensity and the method comprises:
generating a projected laser image utilizing an output beam of the semiconductor laser;
utilizing a gain current control signal generated by the gain current feedback loop to control the gain section of the semiconductor laser; and
narrowing wavelength fluctuations of the semiconductor laser by incorporating a wavelength recovery operation in a drive current of the semiconductor laser, wherein the wavelength recovery operation is sufficient to deplete photon density at a targeted wavelength of the semiconductor laser and is initiated as a function of an optical intensity error signal.

17. A method as claimed in claim 16 wherein the optical intensity error signal is generated from a comparison of a reference intensity and an optical intensity signal generated by the optical intensity monitor.

18. A method as claimed in claim 16 wherein the wavelength recovery operation is further initiated as a function of the gain current control signal.

19. A method as claimed in claim 1 wherein the projected laser image is generated as a scanned laser image or a spatially modulated non-scanned laser image.
